(19) United States
(12) Patent Application Publication
(10) Pub. No.: US 2024/0313098 A1
(43) Pub. Date: Sep. 19, 2024

(54) TRANSISTOR ARCHITECTURES IN COUPLED SEMICONDUCTOR SYSTEMS

(71) Applicant: Micron Technology, Inc., Boise, ID (US)

(72) Inventors: James Brian Johnson, Boise, ID (US); Brent Keeth, Boise, ID (US); Kunal R. Parekh, Boise, ID (US); Eiichi Nakano, Boise, ID (US); Amy Rae Griffin, Boise, ID (US)

(21) Appl. No.: 18/598,735

(22) Filed: Mar. 7, 2024

Related U.S. Application Data
(60) Provisional application No. 63/490,043, filed on Mar. 14, 2023.

(51) Int. Cl. H01L 29/775; H01L 23/00; H01L 25/065; H01L 27/088; H01L 29/423; H01L 29/66; H01L 29/786; H10B 12/00

(52) U.S. Cl. CPC H01L 29/775; H01L 24/80; H01L 25/0657; H01L 27/0886; H01L 29/42392; H01L 29/66439; H01L 29/78696; H01L 2224/80895; H01L 2924/1436; H10B 12/01

(57) ABSTRACT

Methods, systems, and devices for transistor architectures in coupled semiconductor systems are described. A memory system may be formed from multiple semiconductor components (e.g., multiple dies, multiple wafers) that are coupled together, with different semiconductor components implementing different techniques for transistor formation. For example, a first die may include a memory array and first circuitry configured to access the memory array, and a second die coupled with the first die may include second circuitry configured to access the memory array. The first circuitry may include transistors formed in accordance with a first fabrication technique (e.g., to form a first type of transistors) and the second circuitry may include transistors formed in accordance with a second fabrication technique (e.g., to form a second type of transistors). The dies may be coupled in a manner that provides an electrical coupling between the first circuitry and the second circuitry.

### CROSS REFERENCE

The present application for patent claims the benefit of U.S. Provisional Patent Application No. 63/490,043 by JOHNSON et al., entitled “TRANSISTOR ARCHITECTURES IN COUPLED SEMICONDUCTOR SYSTEMS,” filed Mar. 14, 2023, assigned to the assignee hereof, and expressly incorporated by reference in its entirety herein.

### TECHNICAL FIELD

The following relates to one or more systems for memory, including transistor architectures in coupled semiconductor systems.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 illustrates an example of a system that supports transistor architectures in coupled semiconductor systems in accordance with examples as disclosed herein.

FIG. 2 illustrates an example of a memory die that supports transistor architectures in coupled semiconductor systems in accordance with examples as disclosed herein.

FIG. 3 through 5 illustrate examples of transistor architectures that are supported in coupled semiconductor systems in accordance with examples as disclosed herein.

FIG. 6 illustrates an example of an architecture that supports transistor architectures in coupled semiconductor systems in accordance with examples as disclosed herein.

FIGS. 7 and 8 illustrate flowcharts showing methods that support transistor architectures in coupled semiconductor systems in accordance with examples as disclosed herein.

### DETAILED DESCRIPTION

Semiconductor systems, such as semiconductor memory systems, may be fabricated with various implementations of electrical circuitry. When such circuitry is fabricated on a single semiconductor component (e.g., a semiconductor wafer, a semiconductor die), the circuitry may be limited to certain techniques for fabrication that support certain characteristics of the circuitry, such as certain types or characteristics of transistors. For example, a first technique for semiconductor component fabrication may include operations to form planar transistors, where a channel is formed from a doped portion at a surface (e.g., a planar surface) of a substrate and a gate is formed over a single side (e.g., a single face) of the channel. A second technique for semiconductor component fabrication may include operations to form fin field effect transistors (FinFETs), which may include forming trenches through at least a portion of a substrate beside transistor channels (e.g., to expose multiple faces of the substrate to form a channel) and forming gates that are disposed partially around each channel (e.g., around more than a single face of the channel, a gate that is at least partially concave). A third technique for semiconductor component fabrication may include operations to form field effect transistors having all-around gates, where one or more channel portions of a transistor are formed above a substrate (e.g., using a semiconductor deposition operation), and a gate of the transistor is formed around the one or more channel portions (e.g., with the one or more channel portions passing through the gate). Each of such techniques may also be implemented in accordance with various variations (e.g., modified techniques), such as implementations of such techniques with different transistor sizes, different quantities of channel or gate portions, different relative or absolute dimensions, or different channel orientations, among other variations. Although different portions of circuitry of a semiconductor system (e.g., different transistors of a data path for accessing memory cells) may be associated with different functional parameters, forming transistors using different techniques on a single semiconductor component to support the different operating parameters may be impractical due to manufacturing differences between different techniques, process incompatibilities between different techniques or between a technique and other circuitry implemented on a same semiconductor component, process complexities (e.g., complexity related to combining multiple fabrication techniques on a same semiconductor component), or cost, among other considerations.

In accordance with examples as disclosed herein, a semiconductor system, such as a memory system, may be formed from multiple semiconductor components that are coupled together (e.g., bonded, fused), with different semiconductor components implementing different techniques for transistor formation. For example, a set of one or more first dies or wafers (e.g., memory dies or wafers, semiconductor dies or wafers) of a semiconductor system may each include a memory array and first circuitry configured to access the memory array (e.g., a first portion of a data path). A set of one or more second dies or wafers, coupled with the set of one or more first dies or wafers, may include second circuitry configured to access the memory array (e.g., a second portion of the data path). The first circuitry may include transistors formed in accordance with a first fabrication technique (e.g., to form a first type of transistors) and the second circuitry may include transistors formed in accordance with a second fabrication technique (e.g., to form a second type of transistors).

The dies or wafers may be coupled in a manner that provides an electrical coupling between the first circuitry and the second circuitry, which may include a fusion between contacts of the respective dies or wafers, a fusion of an oxide layer at the surfaces of the respective dies or wafers (e.g., in a hybrid bonding implementation, to support a physical coupling), among other types of coupling or combinations thereof. In some examples, such techniques may be implemented to combine relatively low-cost manufacturing of commoditized memory dies or wafers with a more-complex or more-costly manufacturing of high-performance of high-speed logic dies or wafers, or to implement transistors of a second die or wafer that may be incompatible with fabrication operations implemented to form portions of the first dies or wafers (e.g., to form storage elements of memory cells). These and other techniques in accordance with examples as disclosed herein may be implemented to improve an alignment of fabrication, assembly, or performance characteristics with different functional parameters of different portions of semiconductor system circuitry.

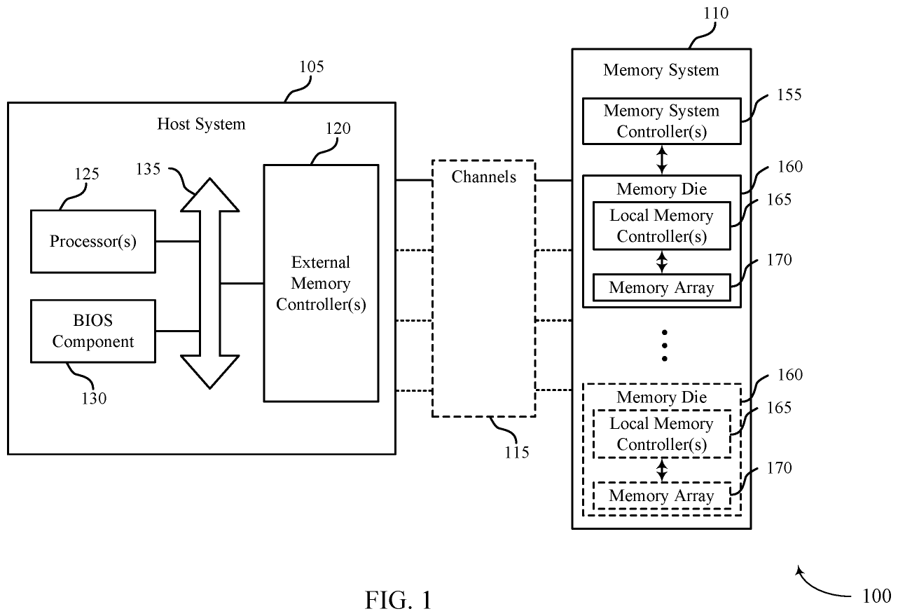

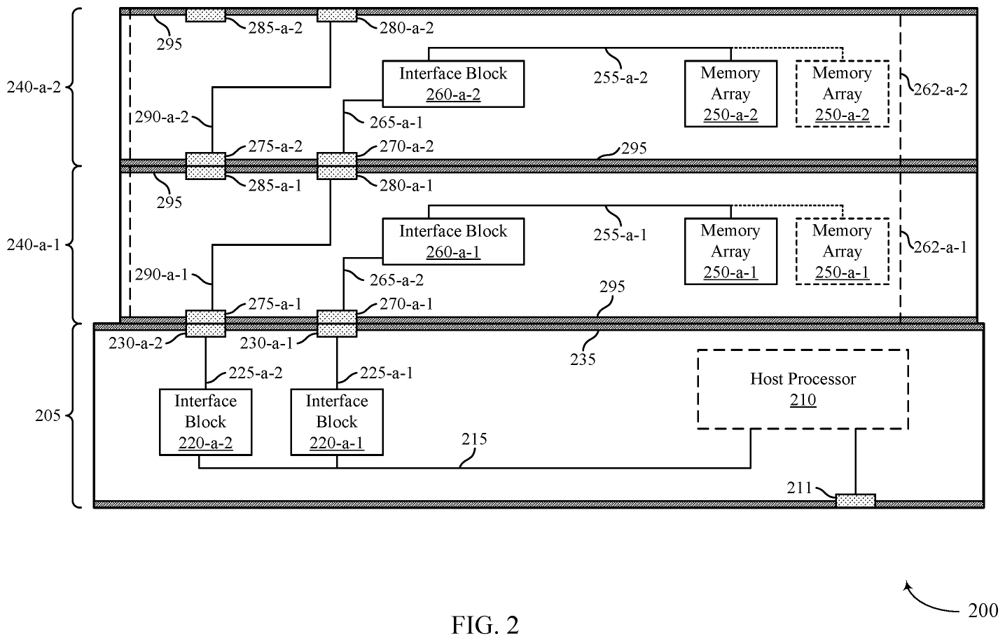

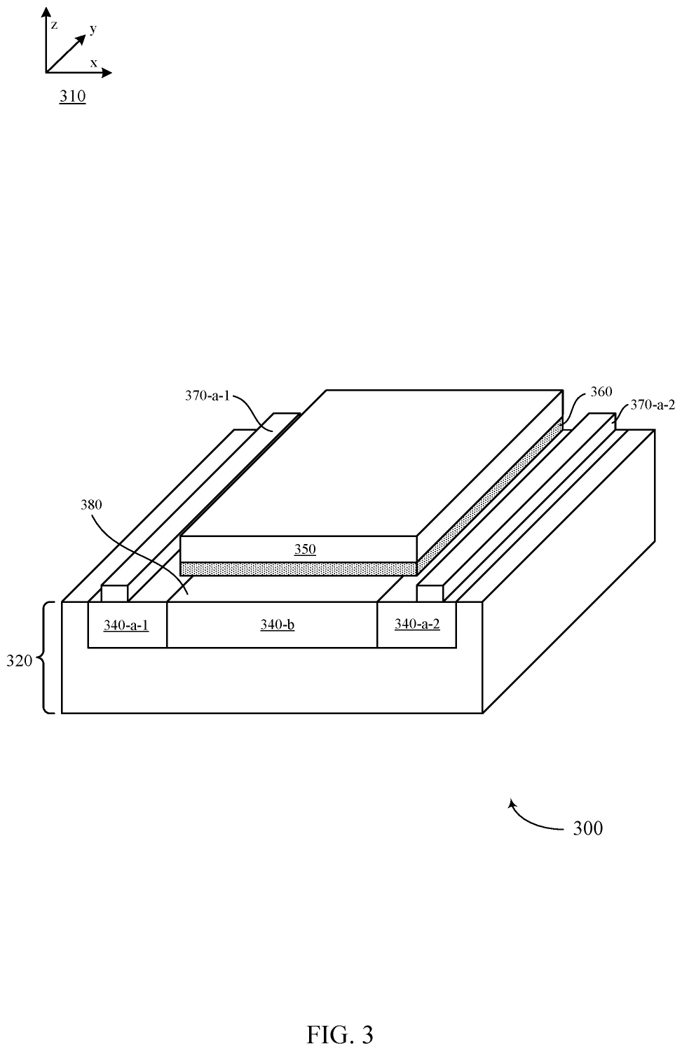

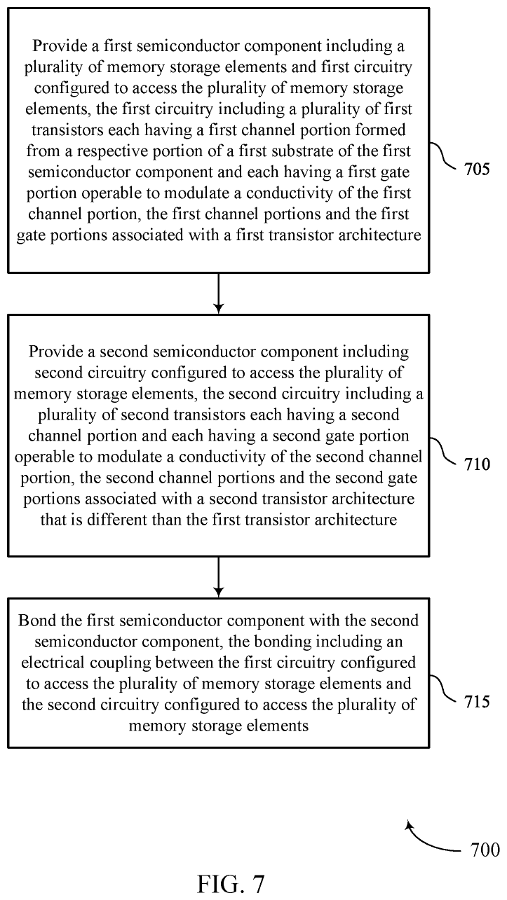

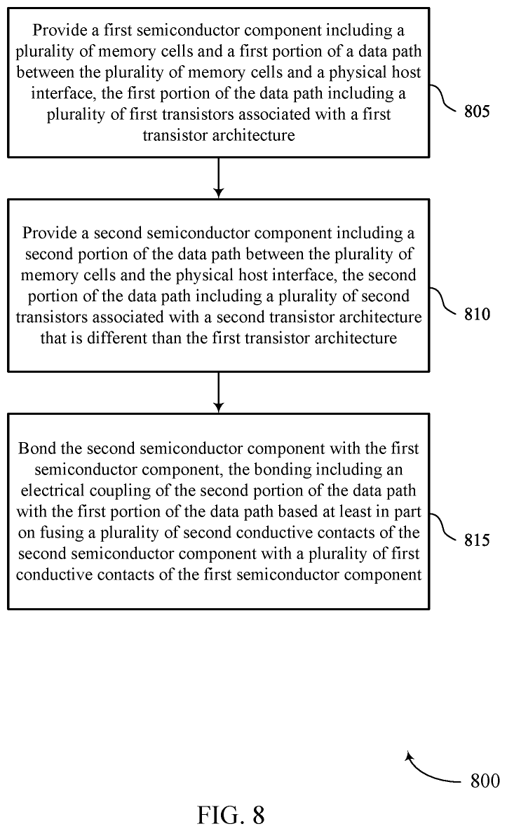

Features of the disclosure are initially described in the context of systems and dies as described with reference to FIGS. 1 and 2. Features of the disclosure are described in the context of semiconductor components (e.g., wafers, dies) as described with reference to FIGS. 3 through 6. These and other features of the disclosure are further illustrated by and described with reference to an apparatus diagram and flowcharts that relate to transistor architectures in coupled semiconductor systems as described with reference to FIGS. 7 and 8.

FIG. 1 illustrates an example of a system 100 that supports transistor architectures in coupled semiconductor systems in accordance with examples as disclosed herein. The system 100 may include portions of an electronic device, such as a computing device, a mobile computing device, a wireless communications device, a graphics processing device, a vehicle, or other systems. The system 100 includes a host system 105, a memory system 110, and one or more channels 115 coupling the host system 105 with the memory system 110 (e.g., to provide a communicative coupling). The system 100 may include one or more memory systems 110, but aspects of the one or more memory systems 110 may be described in the context of a single memory system 110.

The host system 105 may be an example of a processor (e.g., circuitry, processing circuitry, a processing component) that uses memory to execute processes, such as a processing system of a computing device, a mobile computing device, a wireless communications device, a graphics processing device, a wearable device, an internet-connected device, a vehicle controller, a system on a chip (SoC), or other stationary or portable electronic device, among other examples. The host system 105 may include one or more of one or more external memory controller(s) 120, one or more processor(s) 125, a basic input/output system (BIOS) component 130, or other components (e.g., a peripheral component, an input/output controller, not shown). The components of the host system 105 may be coupled with one another using a bus 135.

An external memory controller 120 may be configured to enable communication of information (e.g., data, commands, control information, configuration information) between components of the system 100 (e.g., between components of the host system 105, such as the processor 125, and the memory system 110). An external memory controller 120 may process (e.g., convert, translate) communications exchanged between the host system 105 and the memory system 110. In some examples, an external memory controller 120, or other component of the system 100, or associated functions described herein, may be implemented by or be part of the processor 125. For example, an external memory controller 120 may be hardware, firmware, or software (e.g., instructions), or some combination thereof implemented by a processor 125 or other component of the system 100 or the host system 105. Although an external memory controller 120 is illustrated outside the memory system 110, in some examples, an external memory controller 120, or its functions described herein, may be implemented by one or more components of a memory system 110 (e.g., one or more memory system controllers 155, one or more local memory controllers 165) or vice versa. In various examples, the host system 105 or an external memory controller 120 may be referred to as a host.

A processor 125 may be operable to provide functionality (e.g., control functionality) for the system 100 or the host system 105. A processor 125 may be a general-purpose processor, a digital signal processor (DSP), an application-specific integrated circuit (ASIC), a field-programmable gate array (FPGA) or other programmable logic device, discrete gate or transistor logic, discrete hardware components, or any combination thereof. In some examples, a processor 125 may be an example of a central processing unit (CPU), a graphics processing unit (GPU), a general-purpose GPU (GPGPU), or an SoC, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The memory system 110 may be a component of the system 100 that is operable to provide physical memory locations (e.g., addresses) that may be used or referenced by the system 100. The memory system 110 may include a memory system controller 155 and one or more memory dies 160 (e.g., memory chips) to support a capacity for data storage. The memory system 110 may be configurable to work with one or more different types of host systems 105, and may respond to and execute commands provided by the host system 105 (e.g., via an external memory controller 120). For example, the memory system 110 (e.g., a memory system controller 155) may receive a write command indicating that the memory system 110 is to store data received from the host system 105, or receive a read command indicating that the memory system 110 is to provide data stored in a memory die 160 to the host system 105, or receive a refresh command indicating that the memory system 110 is to refresh data stored in a memory die 160, among other types of commands and operations.

A memory system controller 155 may include components (e.g., circuitry, logic) operable to control operations of the memory system 110. A memory system controller 155 may include hardware, firmware, or instructions that enable the memory system 110 to perform various operations, and may be operable to receive, transmit, or execute commands, data, or control information related to operations of the memory system 110. A memory system controller 155 may be operable to communicate with one or more of an external memory controller 120, one or more memory dies 160, or a processor 125. In some examples, a memory system controller 155 may control operations of the memory system 110 in cooperation with a local memory controller 165 of a memory die 160.

Each memory die 160 may include a local memory controller 165 and a memory array 170. A memory array 170 may be a collection of memory cells, with each memory cell being operable to store one or more bits of data. A memory die 160 may include a two-dimensional (2D) array of memory cells, or a three-dimensional (3D) array of memory cells. In some examples, a 2D memory die 160 may include a single memory array 170. In some examples, a 3D memory die 160 may include two or more memory arrays 170, which may be stacked or positioned beside one another (e.g., relative to a substrate).

A local memory controller 165 may include components (e.g., circuitry, logic) operable to control operations of a memory die 160. In some examples, a local memory controller 165 may be operable to communicate (e.g., receive or transmit data or commands or both) with a memory system controller 155. In some examples, a memory system 110 may not include a memory system controller 155, and a local memory controller 165 or an external memory controller 120 may perform various functions described herein. As such, a local memory controller 165 may be operable to communicate with a memory system controller 155, with other local memory controllers 165, or directly with an external memory controller 120, or a processor 125, or any combination thereof. Examples of components that may be included in a memory system controller 155 or a local memory controller 165 or both may include receivers for receiving signals (e.g., from the external memory controller 120), transmitters for transmitting signals (e.g., to the external memory controller 120), decoders for decoding or demodulating received signals, encoders for encoding or modulating signals to be transmitted, sense components for sensing states of memory cells of a memory array 170, write components for writing states to memory cells of a memory array 170, or various other components operable for supporting described operations of a memory system 110.

A host system 105 (e.g., an external memory controller 120) and a memory system 110 (e.g., a memory system controller 155) may communicate information (e.g., data, commands, control information, configuration information) using one or more channels 115. Each channel 115 may be an example of a transmission medium that carries information, and each channel 115 may include one or more signal paths (e.g., a transmission medium, an electrical conductor, an electrically conductive path) between terminals associated with the components of the system 100. For example, a channel 115 may be associated with a first terminal (e.g., including one or more pins, including one or more pads) at the host system 105 and a second terminal at the memory system 110. A terminal may be an example of a conductive input or output point of a device of the system 100, and a terminal may be operable to act as part of a channel 115. In some implementations, at least the channels 115 between a host system 105 and a memory system 110 may include or be referred to as a host interface (e.g., a physical host interface). In some implementations, a host interface may include interface circuitry (e.g., signal drivers, signal latches) at the host system 105 (e.g., at an external memory controller 120), or at the memory system 110 (e.g., at a memory system controller 155), or both.

In some examples, a channel 115 (e.g., associated signal paths and terminals) may be dedicated to communicating one or more types of information. For example, the channels 115 may include one or more command and address channels, one or more clock signal channels, one or more data channels, among other channels or combinations thereof. In some examples, signaling may be communicated over the channels 115 using single data rate (SDR) signaling or double data rate (DDR) signaling. In SDR signaling, one modulation symbol (e.g., signal level) of a signal may be registered for each clock cycle (e.g., on a rising or falling edge of a clock signal). In DDR signaling, two modulation symbols of a signal may be registered for each clock cycle (e.g., on both a rising edge and a falling edge of a clock signal).

Semiconductor systems, such as a memory system 110, may be fabricated with various implementations of electrical circuitry (e.g., of a memory system controller 155, of one or more local memory controllers 165, of one or more memory arrays 170). When such circuitry is fabricated on a single semiconductor component (e.g., a semiconductor wafer, a semiconductor die), the circuitry may be limited to certain techniques for fabrication that support certain characteristics of the circuitry, such as certain types or characteristics of transistors. For example, a first technique for semiconductor component fabrication may include operations to form planar transistors, where a channel is formed from a doped portion at a surface (e.g., a planar surface) of a substrate and a gate is formed over a single side (e.g., a single face) of the channel. A second technique for semiconductor component fabrication may include operations to form fin field effect transistors (FinFETs), which may include forming trenches through at least a portion of a substrate beside transistor channels (e.g., to expose multiple faces of the substrate to form a channel) and forming gates that are disposed partially around each channel (e.g., around more than a single face of the channel, a gate that is at least partially concave). A third technique for semiconductor component fabrication may include operations to form field effect transistors having all-around gates, where one or more channel portions of a transistor are formed above a substrate (e.g., using a semiconductor deposition operation), and a gate of the transistor is formed around the one or more channel portions (e.g., with the one or more channel portions passing through the gate). Each of such techniques may also be implemented in accordance with various variations (e.g., modified techniques), such as implementations of such techniques with different transistor sizes, different quantities of channel or gate portions, different relative or absolute dimensions, or different channel orientations, among other variations.

Although different portions of circuitry of a semiconductor system (e.g., different transistors of a data path for accessing memory cells of memory arrays 170) may be associated with different functional parameters, forming transistors using different techniques on a single semiconductor component to support the different operating parameters may be impractical due to manufacturing differences between different techniques, process incompatibilities between different techniques or between a technique and other circuitry implemented on a same semiconductor component, materials integrated to build the transistors and interconnects, process complexities (e.g., complexity related to combining multiple fabrication techniques on a same semiconductor component), or cost, among other considerations. In other words, processing incompatibilities may limit or prohibit a coexistence of different transistor architectures on the same semiconductor substrate. The different requirements for manufacturing different transistor architectures may impact the memory system 110 beyond the transistors themselves. For example, a layout design, parasitic components, or thermal requirements of the memory system 110, or a combination thereof, may be impacted.

In accordance with examples as disclosed herein, a semiconductor system, such as a memory system 110, may be formed from multiple semiconductor components that are coupled together (e.g., bonded, fused), with different semiconductor components implementing different techniques for transistor formation (e.g., a semiconductor system comprising a processed chip bonded with a memory stack in a monolithic, electrical package). For example, a first semiconductor component (e.g., a set of one or more first dies or wafers, semiconductor dies, memory dies) of a semiconductor system may include one or more memory arrays 170 and first circuitry configured to access the one or more memory arrays 170 (e.g., a first portion of a data path), and a second semiconductor component (e.g., a set of one or more second dies or wafers, semiconductor dies, logic dies) coupled with the first semiconductor component may include second circuitry configured to access the one or more memory arrays 170 (e.g., a second portion of the data path). The first circuitry may include transistors formed in accordance with a first fabrication technique (e.g., to form a first type of transistors) and the second circuitry may include transistors formed in accordance with a second fabrication technique (e.g., to form a second type of transistors).

The dies may be coupled in a manner that provides an electrical coupling between the first circuitry and the second circuitry, which may include a fusion between contacts of the respective dies or wafers, a fusion of an oxide layer at the surfaces of the respective dies or wafers (e.g., in a hybrid bonding implementation, to support a physical coupling), among other types of coupling or combinations thereof. In some examples, such techniques may be implemented to combine relatively low-cost manufacturing of commoditized memory dies with a more-complex or more-costly manufacturing of high-performance of high-speed logic dies, or to implement transistors of a second die that may be incompatible with fabrication operations implemented to form portions of the first dies (e.g., to form storage elements of memory cells of memory arrays 170). These and other techniques in accordance with examples as disclosed herein may be implemented to improve an alignment of fabrication, assembly, or performance characteristics with different functional parameters of different portions of semiconductor system circuitry in system 100.

FIG. 2 illustrates an example of a system 200 (e.g., a semiconductor system, a system of coupled semiconductor dies) that supports transistor architectures in coupled semiconductor systems in accordance with examples as disclosed herein. The system 200 illustrates an example of a die 205 (e.g., a semiconductor die, a logic die, a processor die, a host die, a buffer layer) that is coupled with one or more dies 240 (e.g., dies 240-a-1 and 240-a-2, semiconductor dies, memory dies, array dies). Although aspects of the die 205 are described in the context of a single die, in some other examples, aspects of the die 205 may be distributed among multiple dies that are coupled in accordance with examples as disclosed herein. A die 205 or a die 240 may be formed using a respective semiconductor substrate (e.g., a substrate of crystalline semiconductor material such as silicon, germanium, silicon-germanium alloy, gallium arsenide or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240 coupled with one die 205, a system 200 in accordance with the described techniques may include any quantity of one or more dies 240 coupled with one or more dies 205.

The system 200 illustrates an example of interface circuitry between a host and memory (e.g., via a host interface, via a physical host interface) that is implemented in (e.g., divided between) multiple semiconductor dies. For example, the die 205 may include a set of one or more interface blocks 220 (e.g., interface blocks 220-a-1 and 220-a-2, memory interface blocks), and each die 240 may include a set of one or more interface blocks 260 and one or more memory arrays 250 (e.g., die 240-a-1 including an interface block 260-a-1 coupled with a set of one or more memory arrays 250-a-1, die 240-a-2 including an interface block 260-a-2 coupled with a set of one or more memory arrays 250-a-2). Memory arrays 250 may be examples of memory arrays 170. In some implementations, the die 205 also may include a host processor 210. However, in some other implementations, a host processor 210 may be external to a die 205, such as in another semiconductor die or other component that is coupled with (e.g., communicatively coupled with, directly coupled with, bonded with, fused with) the die 205 via one or more contacts 211. Although the example of system 200 is illustrated with one interface block 260 included in each die 240, a die 240 in accordance with the described techniques may include any quantity of one or more interface blocks 260, each coupled with a respective set of one or more memory arrays 250, and each coupled with a respective interface block 220 of a die 205. Thus, the interface circuitry of a system 200 may include one or more interface blocks 220 of a die 205, with each interface block 220 being coupled with (e.g., in communication with) a corresponding interface block 260 of a die 240 (e.g., external to the die 205). In some examples, a coupled combination of an interface block 220 and an interface block 260 may include or be referred to as a data path associated with a respective set of one or more memory arrays 250.

A host processor 210 may be an example of a host system 105, or a portion thereof (e.g., a processor 125, an external memory controller 120, or both). The host processor 210 may be configured to perform operations that implement storage of the memory arrays 250. For example, the host processor 210 may receive data read from the memory arrays 250, or transmit data to be written to the memory arrays 250, or both (e.g., in accordance with an application or other operations of the host processor 210). The memory arrays 250 may be examples of memory arrays 170, and may include memory cells of various architectures, such as RAM, DRAM, SDRAM, SRAM, FORAM, MRAM, RRAM, PCM, chalcogenide, NOR, or NAND memory cells, or any combination thereof. The host processor 210 may be configured to communicate (e.g., transmit, receive) signaling with the interface blocks 220 over a bus 215, which may implement aspects of channels 115 described with reference to FIG. 1. For example, the host processor 210 may be configured to transmit access signaling (e.g., control signaling, access command signaling), which may be received by the interface blocks 220 to support access operations (e.g., read operation, write operations) on the memory arrays 250.

A bus 215 may include a respective set of one or more signal paths for each interface block 220, such that the host processor 210 communicates with each interface block 220 over the respective set of signal paths (e.g., in accordance with a selection of the respective set to perform access operations via an interface block 220 that is selected by the host processor 210). Additionally, or alternatively, a bus 215 may include one or more signal paths that are shared among multiple interface blocks 220, and an interface block 220, or a host processor 210, or both may interpret, ignore, respond to, or inhibit response to signaling over shared signal paths of the bus 215 based on a logical indication (e.g., an addressing indication associated with the interface block 220 or an interface enable signal, which may be provided by the host processor 210 or the corresponding interface block 220, depending on signaling direction). A bus 215 may be an example of a host interface (e.g., a physical host interface) between aspects of a host system 105 (e.g., a host processor 210, of the die 205 or external to the die 205) and a memory system 110 (e.g., including interface blocks 220, interface blocks 260, and memory arrays 250).

Each interface block 220 may be coupled with at least a respective bus 225 of the die 205, and a respective bus 265 of a die 240, that is configured to communicate signaling with the corresponding interface block 260 (e.g., over one or more associated signal paths). For example, the interface block 220-a-1 may be coupled with the interface block 260-a-1 via a bus 225-a-1 and a bus 265-a-1, and the interface block 220-a-2 may be coupled with the interface block 260-a-2 via a bus 225-a-2 and a bus 265-a-2. In some examples, a die 240 may include a bus that bypasses operational circuitry of the die 240 (e.g., bypasses interface blocks 260 of a given die 240), such as a bus 290. For example, the interface block 220-a-2 may be coupled with the interface block 260-a-2 of the die 240-a-2 via a bus 290-a-1 of the die 240-a-1, which may bypass interface blocks 260 of the die 240-a-1. Such techniques may be extended for interconnection among more than two dies 240 (e.g., for interconnection via a respective bus 290 of multiple dies 240).

The respective signal paths of the buses 225, 265, and 290 may be coupled with one another, from one die to another, via various arrangements of contacts at the surfaces of interfacing dies. For example, the bus 225-a-1 may be coupled with the bus 265-a-1 via a contact 230-a-1 of (e.g., at a surface of) the die 205 and a contact 270-a-1 of the die 240-a-1, the bus 225-a-2 may be coupled with the bus 290-a-1 via a contact 230-a-2 of the die 205 and a contact 275-a-1 of the die 240-a-1, the bus 290-a-1 may be coupled with the bus 265-a-2 via a contact 280-a-1 of the die 240-a-1 and a contact 270-a-2 of the die 240-a-2, and so on. Although each respective bus is illustrated with a single line, coupled via singular contacts, it is to be understood that each signal path of a bus may be associated with respective contacts to support a separate communicative coupling via each signal path of a given bus. In some examples, a bus 290 may traverse a portion of a die 240 (e.g., in an in-plane direction, along a direction different from a thickness direction, in a waterfall arrangement), which may support an arrangement of contacts 230 along a surface of the die 205 being coupled with interface blocks 260 of different dies 240 along a stack direction (e.g., via contacts 275 and 280 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205 with the die 240-a-1 may include a conductive material of the contact 230-a-2 being fused with a conductive material of the contact 275-a-1, and the coupling of the die 240-a-1 with the die 240-a-2 may include a conductive material of the contact 280-a-1 being fused with a conductive material of the contact 270-a-2, and so on. In some examples, such coupling may include an inoperative fusion of contacts (e.g., a non-communicative coupling, a physical coupling), such as a fusion of the contact 285-a-1 with the contact 275-a-2, neither of which are coupled with operative circuitry of the dies 240-a-1 or 240-a-2. In some examples, such techniques may be implemented to improve coupling strength or uniformity (e.g., implementing contacts 285, which may not be operatively coupled with an interface block 260 or an interface block 220), or such a coupling may be a byproduct of a repetition of components that, in various configurations, may be operative or inoperative. (e.g., where, for dies 240 with a common arrangement of contacts 275 and 285, contacts 275-a-1 and 280-a-1 provide a communicative path for the interface block 260-a-2 and the interface block 220-a-2, but the contacts 275-a-2 and 280-a-2 do not provide a communicative path between an interface block 260 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205 with the die 240-a-1 may include a dielectric material 235 (e.g., an electrically non-conductive material) of the die 205 being fused with a dielectric material 295 of the die 240-a-1, and the coupling of the die 240-a-1 with the die 240-a-2 may include a dielectric material 295 of the die 240-a-1 being fused with a dielectric material 295 of the die 240-a-2. In some examples, such dielectric materials may include an oxide, a nitride, a carbide, an oxide-nitride, an oxide-carbide, or other conversion or doping of a semiconductor material of the die 205 or dies 240, among other materials that may support such fusion. However, coupling among dies 205 and dies 240 may be implemented in accordance with other techniques, which may implement solder, adhesives, thermal interface materials, and other intervening materials.

In some examples, dies 240 may be coupled in a stack (e.g., forming a “cube” or other arrangement of dies 240), and the stack may subsequently be coupled with a die 205. In some examples, a respective set of one or more dies 240 may be coupled with each die 205 of multiple dies 205 formed in a wafer (e.g., in a chip-to-wafer bonding arrangement, before cutting the wafer of dies 205), and the dies 205, coupled with their respective set of dies 240, may be separated from one another (e.g., by cutting at least the wafer of dies 205). In some other examples, a respective set of one or more dies 240 may be coupled with a respective die 205 after the die 205 is separated from a wafer of dies 205 (e.g., in a chip-to-chip bonding arrangement). In some other examples, a first wafer of dies 240 may be coupled with a second wafer of dies 240 (e.g., forming a stack of wafers including stacks of dies 240), and the stack of wafers may subsequently be coupled with a wafer of dies 205 (e.g., in a wafer-to-wafer bonding arrangement, before separating instances of the system 200 from one another).

The buses 225, 265, and 290 may be configured to provide a configured signaling (e.g., a coordinated signaling, a logical signaling, modulated signaling, digital signaling) between an interface block 220 and a corresponding interface block 260, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 260 (e.g., to trigger signal reception by a latch or other reception component of the interface block 260, to support clocked operations of the interface block 260). Additionally, or alternatively, the buses may be configured to convey one or more clock signals transmitted by the interface block 260 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication) of various, such as control signaling, command signaling, data signaling, or any combination thereof. For example, the buses may include one or more signal paths for communications of a data bus (e.g., a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220 and 260 each may include circuitry in various configurations (e.g., hardware configurations, logic configurations, software or instruction configurations) that support the functionality allocated to the respective interface block for accessing a corresponding set of memory arrays 250. For example, interface blocks 220 may include circuitry configured to perform a first subset of operations that support access of the memory arrays 250, and interface blocks 260 may include circuitry configured to support a second subset of operations that support access of the memory arrays 250. In some examples, the interface blocks 220 and 260 may support a functional split or distribution of functionality associated with a memory system controller 155, a local memory controller 165, or both across multiple dies (e.g., a die 205 and at least one die 240). Such subsets of operations may include operations performed in response to commands from the host processor 210, or operations performed without commands from the host processor 210 (e.g., operations determined within an interface block 220 or within an interface block 260), or various combinations thereof. In some examples, the circuitry of interface blocks 220, or interface blocks 260, or both may include components (e.g., transistors) formed at least in part from doped portions of a substrate of the respective die where, in some examples, a substrate of a die 205 may have characteristics that are different from those of a substrate of a die 240.

In some examples, the interface blocks 220 may include circuitry configured to receive first access command signaling from the host processor 210 (e.g., via a bus 215, via one or more contacts 211, where applicable), and to transmit second access command signaling to the respective (e.g., coupled) interface block 260 based on (e.g., in response to) the received first access command signaling. The interface blocks 260 may accordingly include circuitry configured to receive the second access command signaling from the respective interface block 220, and to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220). Additionally, or alternatively, the interface blocks 220 may include circuitry configured to support command queuing or prioritization, among other command logic.

In some examples, to support write operations of the system 200, circuitry of the interface blocks 220 may be configured to receive (e.g., from the host processor 210, via a bus 215, via one or more contacts 211, where applicable) first data signaling associated with the first access command signaling, and to transmit second data signaling (e.g., associated with second access command signaling) based on received first access command signaling and first data signaling. The interface blocks 260 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 260 may be configured to read data from the memory arrays 250 based on received second access command signaling, and to transmit first data signaling based at least in part on the read data. The interface blocks 220 may accordingly be configured to receive first data signaling, and to transmit second data signaling (e.g., to the host processor 210, via a bus 215, via one or more contacts 211, where applicable) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted by the interface blocks 220 to the interface blocks 260 may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 (e.g., based on a configuration for accessing memory arrays 250 that is modified at the interface blocks 220). Such techniques may support the interface blocks 220 configuring aspects of the access operations performed on the memory arrays 250 by a respective interface block 260.

In some examples, dies 240 may be manufactured on a planar semiconductor component, such as a wafer, which may support multiple configurations of dies 240. For example, a wafer may include a pattern of memory arrays 250 arranged across the wafer along a row direction and a column direction, as well as channels, which may include at least buses 265, associated with the memory arrays 250. A row of memory arrays 250 may be associated with a contact region extending along the row direction, which may include contacts (e.g., contacts 270) for communicating access signaling with memory arrays 250 of the row. The wafer may also include control regions extending along the column direction between at least some of the columns of memory arrays 250, each control region containing control circuitry for operating memory arrays 250 (e.g., circuitry of an associated interface block 260). The wafer may also include a set of separation regions (e.g., scribe lines) separating at least some of the rows and columns of memory arrays 250.

A die 240 may include one or more units 262 (e.g., modules) that are separated from a semiconductor wafer having a pattern of units 262. Although each die 240 of the system 200 is illustrated with a single unit 262 (e.g., unit 262-a-1 of die 240-a-1, unit 262-a-2 of die 240-a-2), a die 240 in accordance with the described techniques may include any quantity of units 262, which may be arranged in various patterns (e.g., sets of one or more units 262 along a row direction, sets of one or more units 262 along a column direction, among other patterns). Each unit 262 may include at least the circuitry of a respective interface block 260, along with memory array(s) 250, a bus 255, a bus 265, and one or more contacts 270 corresponding to the respective interface block 260. In some examples, where applicable, each unit 262 may also include one or more buses 290, contacts 275, contacts 280, or contacts 285 (e.g., associated with a respective interface block 260 of a unit 262 of a different die 240), which may support various degrees of stackability among or via units 262 of other dies 240.

In accordance with examples as disclosed herein, a system 200 (e.g., a logic chip and a memory stack in a monolithic electrical package) may be formed from multiple semiconductor components that are coupled together (e.g., bonded, fused), with different semiconductor components implementing different techniques for transistor formation. For example, the system 200 may include one or more instances of a data path between memory cells of the system 200 (e.g., of the memory arrays 250) and a host interface of the system (e.g., a bus 215), with each instance of a data path including a coupled combination of an interface block 220 and an interface block 260, and, in some examples a portion of one or more memory arrays 250. A first portion of a data path (e.g., at least a portion of interface blocks 260, or memory arrays 250, or both) may include transistors formed in accordance with a first fabrication technique (e.g., a first process flow) and a second portion of the data path (e.g., at least a portion of interface blocks 220), or a host processor 210, or both may include transistors formed in accordance with a second fabrication technique (e.g., a second process flow).

In some examples, a first fabrication technique (e.g., memory manufacturing flow) may be used to fabricate transistors (e.g., FinFETs, planar transistors, DRAM transistors) of a die 240 (e.g., memory die) and a second fabrication technique (e.g., logic manufacturing flow, a foundry process) may be used to fabricate transistors (e.g., FinFETs, all-around gate transistors) of a die 205. The first type of transistors may be used in memory arrays 250 (e.g., for cell selection transistors) or in logical, switching, or addressing circuitry located in interface blocks 260, or a combination thereof. Additionally, or alternatively, the second type of transistor may be used in the second portion of the data path in logical, switching, or addressing circuitry located in interface blocks 220, the host processor 210 or a combination thereof.

In some examples, such techniques may be implemented to combine relatively low-cost manufacturing of commoditized memory dies with a more-complex or more-costly manufacturing of high-performance or high-speed logic dies, or to implement transistors of a second die 205 that may be incompatible with fabrication operations implemented to form portions of the first dies 240 (e.g., to form storage elements of memory cells in memory arrays 250). The transistors of the second die 205 may have characteristics such as high versatility, implementation in a set of standards, high performance, high current gain, high switching speed, low switching power, small geometry, high quantity of interconnect layers, high interconnect density, high circuit density, high power density or a combination thereof compared to the transistors of the first die 240. The transistors of the first die 240 may have low leakage, low manufacturing cost (e.g., associated with a standardized or commoditization of memory chips) compared to transistors of the second die 205. Transistors of the first die 240 may also include layouts that integrate cell selection and multiplexing/decoding transistors with storage components like capacitors or other memory storage elements. Transistors of the second die 205 may allow for customized design with few barriers to modification or customization of host facing protocols or interfaces, which may enable multiple product stock keeping units with an identical fabrication technique (e.g., memory manufacturing flow). Different portions of the circuitry (e.g., DRAM, Logic CMOS) in system 200 may benefit from being fabricated separately from other portions of the circuitry, since various portions of the circuitry may have different processing considerations (e.g., integration requirements, thermal considerations) in order to implement their respective characteristics such as performance and uniformity. Techniques in accordance with examples as disclosed herein may be implemented to improve an alignment of fabrication, assembly, or performance characteristics with different functional parameters of different portions of circuitry in the system 200.

FIG. 3 illustrates an example of a transistor architecture 300 that supports transistor architectures in coupled semiconductor systems in accordance with examples as disclosed herein. The transistor architecture 300 illustrates an example of a transistor that is formed at least in part by portions of a substrate 320 (e.g., doped portions 340 of the substrate 320), and illustrates an arrangement of features for a transistor that is configured in a planar arrangement (e.g., a planar transistor). The substrate 320 may be a portion of a semiconductor wafer, such as a silicon chip (e.g., crystalline silicon, monocrystalline silicon, a substrate having a contiguous crystalline arrangement). For illustrative purposes, aspects of the transistor architecture 300 may be described with reference to an x-direction (e.g., a first direction parallel to, within, or over the substrate 320), a y-direction (e.g., a second direction parallel to, within, or over the substrate 320), and a z-direction (e.g., a height direction, a direction away from the substrate 320) of a coordinate system 310. The z-direction may be illustrative of a direction perpendicular to a surface of the substrate 320 (e.g., a surface in an xy-plane, a surface on which or over which other materials may be deposited).

The transistor architecture 300 illustrates an example of a transistor channel (e.g., along the x-direction) that is electrically coupled between a terminal 370-a-1 and a terminal 370-a-2, which may include one or more doped portions 340 of the substrate 320. In various examples, one of the terminals 370-a-1 or 370-a-2 may be referred to as a source terminal, and the other of the terminals 370-a-1 or 370-a-2 may be referred to as a drain terminal, where such designations may be based on a configuration or relative biasing of a circuit that includes the transistor architecture 300. The channel (e.g., channel portion) of a transistor may include or refer to one or more portions of the transistor architecture 300 that are operable to open or close a conductive path (e.g., to modulate a conductivity, to form a channel, to open a channel, to close a channel) between a source and drain (e.g., between the terminal 370-a-1 and the terminal 370-a-2) based at least in part on a voltage of a gate (e.g., a gate terminal, a gate portion 350) of the transistor. In other words, a channel of the transistor may be configured to be activated (e.g., made conductive) or deactivated (e.g., made non-conductive) based at least in part on a voltage of a gate, such as gate portion 350. In some examples of transistor architecture 300 (e.g., a planar transistor arrangement), the channel may support a conductive path in a horizontal direction (e.g., an “in-plane” direction, along the x-direction, within an xy-plane, in a direction within or parallel to a surface of the substrate 320).

The gate portion 350 may be physically separated from the channel portion (e.g., separated from the substrate 320, separated from one or more of the doped portions 340) by a gate insulation portion 360 (e.g., a gate dielectric). Each of the terminals 370 may be in contact with or otherwise coupled with (e.g., electrically, physically) a respective doped portion 340-a, and each of the terminals 370 and the gate portion 350 may be formed from an electrically conductive material such as a metal or metal alloy, or a polycrystalline semiconductor (e.g., polysilicon), among other conductor or semiconductor arrangements formed above the substrate 320. The doped portions 340 of the transistor architecture 300 illustrate an example of a channel portion of a transistor that is located beside a gate portion (e.g., gate portion 350). For example, the transistor architecture 300 illustrates an example of the gate portion 350 being located along one side of (e.g., a top side 380) the channel formed by doped portions 340.

In some examples, the transistor architecture 300 may be operable as an n-type (e.g., n-channel) transistor, where applying a relatively positive voltage to the gate portion 350 that is above a threshold voltage (e.g., an applied voltage having a positive magnitude, relative to a source terminal, that is greater than a threshold voltage) activates the channel portion or otherwise enables a conductive path between the terminals 370-a-1 and 370-a-2 (e.g., along a direction aligned with the x-direction within the substrate 320). In some such examples, the doped portions 340-a may refer to portions having n-type doping or n-type semiconductor, and the doped portion 340-b may refer to a portion having p-type doping or p-type semiconductor (e.g., a channel portion having an NPN configuration along the x-direction or channel direction).

In some other examples, the transistor architecture 300 may be operable as a p-type (e.g., p-channel) transistor, where applying a relatively negative voltage to the gate portion 350 that is above a threshold voltage (e.g., an applied voltage having a negative magnitude, relative to a source terminal, that is greater than a threshold voltage) activates the channel portion or otherwise enables a conductive path between the terminals 370-a-1 and 370-a-2. In some such examples, the doped portions 340-a may refer to portions having p-type doping or p-type semiconductor, and doped portion 340-b may refer to a portion having n-type doping or n-type semiconductor (e.g., a channel portion having a PNP configuration along the x-direction or channel direction).

In some examples, circuitry operable to support access operations on memory cells in a memory array 170 may be formed to include at least some transistors formed in accordance with the transistor architecture 300. In some examples, circuitry in dies 205 (e.g., in one or more interface blocks 220, in a host processor 210, where applicable), in dies 240 (e.g., in one or more interface blocks 260, as cell selection transistors in one or more memory arrays 250), or both may be formed to include respective sets of transistors each having the arrangement of the transistor architecture 300. Although illustrated as having a channel being formed from doped substrate, in some other examples, the transistor architecture 300 may be implemented with channel portions that are formed from semiconductor portions formed above a substrate 320. In some examples, transistors may leverage a crystalline semiconductor material of the substrate 320 for various performance characteristics or manufacturing characteristics of such a material or such an arrangement. Some examples of such an arrangement may be implemented in a complementary metal-oxide-semiconductor (CMOS) configuration, which may refer to various examples of a complementary and symmetrical pair of a p-type transistor and an n-type transistor (e.g., for logic functions).

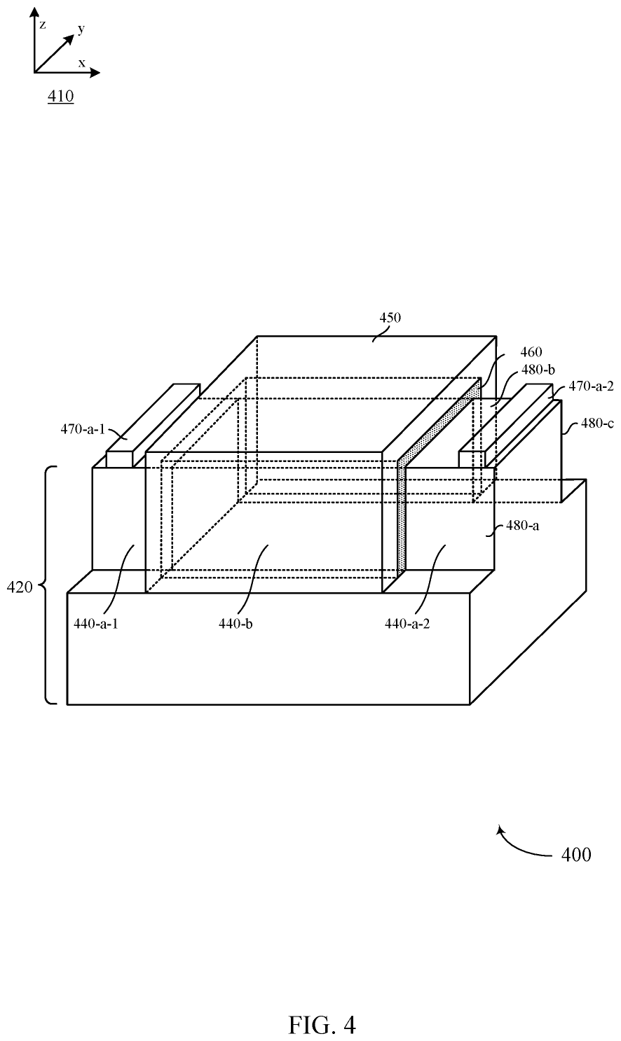

FIG. 4 illustrates an example of a transistor architecture 400 that supports transistor architectures in coupled semiconductor systems in accordance with examples as disclosed herein. The transistor architecture 400 illustrates an example of a transistor that is formed at least in part by portions of a substrate 420 (e.g., doped portions 440 of the substrate 420), and illustrates an arrangement of features for a transistor that is configured in a FinFET arrangement (e.g., a FinFET transistor). The substrate 420 may be a portion of a semiconductor wafer, such as a silicon chip. For illustrative purposes, aspects of the transistor architecture 400 may be described with reference to an x-direction (e.g., a first direction parallel to, within, or over the substrate 420), a y-direction (e.g., a second direction parallel to, within, or over the substrate 420), and a z-direction (e.g., a height direction, a direction away from the substrate 420) of a coordinate system 410.

The transistor architecture 400 illustrates an example of a transistor channel (e.g., along the x-direction) that is electrically coupled between a terminal 470-a-1 and a terminal 470-a-2, which may include one or more doped portions 440 of the substrate 420. The channel may be formed by forming trenches through at least a portion of the substrate 420 (e.g., around or beside the channel, extending along the x-direction) to allow a gate portion 450 to interface multiple sides 480 of the channel. In some examples of transistor architecture 400, the channel portion may support a conductive path in a horizontal direction (e.g., an “in-plane” direction, along the x-direction, within an xy-plane, in a direction within or parallel to a surface of the substrate 420).

The gate portion 450 may be physically separated from the channel portion by a gate insulation portion 460. The gate portion 450 may be formed from an electrically conductive material such as a metal or metal alloy, or a polycrystalline semiconductor (e.g., polysilicon), among other conductor or semiconductor arrangements formed beside or along the channel portion. The transistor architecture 400 illustrates an example of gate portion 450 being located along three sides (e.g., a top side 480-b, a side 480-a, and a side 480-c) of a channel formed by doped portions 440. For example, the gate portion 450 wraps around the doped portions 440 over three sides (e.g., three surfaces). In some implementations of the transistor architecture 400, a gate portion 450 may wrap around doped portions 440 with a concave shape in a different way than illustrated in FIG. 4. The channel, for example, may have a non-rectangular cross-section, or the gate may not be located along the entire top side 480-b, or sides 480-a and 480-c (e.g., vertical sides in an xz-plane), or a combination thereof. The doped portions 440 of the transistor architecture 400 illustrate an example of a channel portion that is located beside the gate portion 450.

In some examples, the transistor architecture 400 may be operable as an n-type transistor, where applying a relatively positive voltage to the gate portion 450 that is above a threshold voltage activates the channel portion or otherwise enables a conductive path between the terminals 470-a-1 and 470-a-2. In some such examples, the doped portions 440-a may refer to portions having n-type doping or n-type semiconductor, and the doped portion 440-b may refer to a portion having p-type doping or p-type semiconductor. In some other examples, the transistor architecture 400 may be operable as a p-type transistor, where applying a relatively negative voltage to the gate portion 450 that is above a threshold voltage activates the channel portion or otherwise enables a conductive path between the terminals 470-a-1 and 470-a-2. In some such examples, the doped portions 440-a may refer to portions having p-type doping or p-type semiconductor, and doped portion 440-b may refer to a portion having n-type doping or n-type semiconductor.

In some examples, circuitry operable to support access operations on memory cells in memory array 170 may be formed to include at least some transistors formed in accordance with the transistor architecture 400. In some examples, circuitry in dies 205 (e.g., in one or more interface blocks 220, in a host processor 210, where applicable), in dies 240 (e.g., in one or more interface blocks 260, as cell selection transistors in one or more memory arrays 250), or both may be formed to include respective sets of transistors each having the arrangement of the transistor architecture 400. Although illustrated as having a channel being formed from doped substrate, in some other examples, the transistor architecture 400 may be implemented with channel portions that are formed from semiconductor portions formed above a substrate 420. In some examples, transistors may leverage a crystalline semiconductor material of the substrate 420 for various performance characteristics or manufacturing characteristics of such a material or such an arrangement. Some examples of such an arrangement may be implemented in a complementary metal-oxide-semiconductor (CMOS) configuration, which may refer to various examples of a complementary and symmetrical pair of a p-type transistor and an n-type transistor (e.g., for logic functions). Although the transistor architecture 400 may be more complex to manufacture than the transistor architecture 300 (e.g., due to trenching and other operations), or may be associated with lower transistor density (e.g., in an xy-plane, to accommodate the gate portion 450 interfacing multiple sides of the doped portions 440), in some examples, the transistor architecture 400 may have other favorable performance such as improved channel characteristics (e.g., lower leakage, lower threshold voltages, steeper activation performance, lower activation latency) relative to the transistor architecture 300, among other characteristics that may be favorable for certain aspects of a data path.

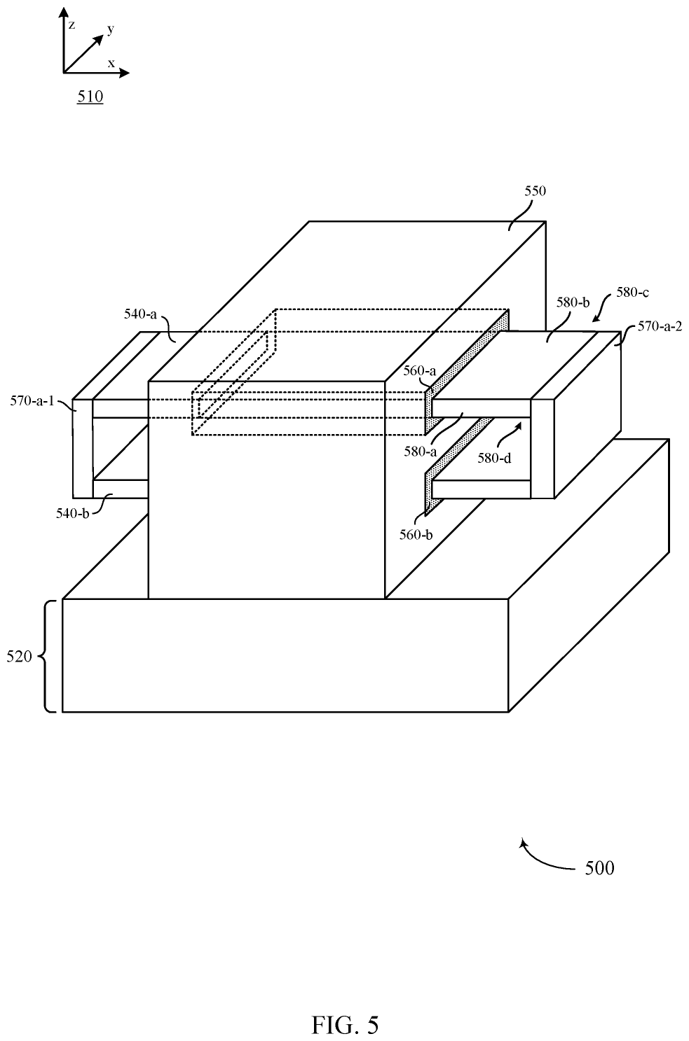

FIG. 5 illustrates an example of a transistor architecture 500 that supports transistor architectures in coupled semiconductor systems in accordance with examples as disclosed herein. The transistor architecture 500 illustrates an example of a transistor that is formed above a substrate 520, and illustrates an arrangement of features for a transistor that is configured in an all-around gate arrangement. The substrate 520 may be a portion of a semiconductor wafer, such as a silicon chip. For illustrative purposes, aspects of the transistor architecture 500 may be described with reference to an x-direction (e.g., a first direction parallel to, within, or over the substrate 520), a y-direction (e.g., a second direction parallel to, within, or over the substrate 520), and a z-direction (e.g., a height direction, a direction away from the substrate 520) of a coordinate system 510.

The transistor architecture 500 illustrates an example of a transistor channel (e.g., including channel portions 540 along the x-direction) that is electrically coupled between a terminal 570-a-1 and a terminal 570-a-2, where each of the channel portions 540 may include one or more doped portions of a semiconductor material that is formed (e.g., by deposition, by epitaxy) above the substrate 520. For example, the channel portions 540 may include doped portions of silicon, or of silicon-germanium, or other semiconductor materials, and may include salicide junctions (e.g., of or between doped portions). In some implementations of transistor architecture 500, the channel portion may support a conductive path in a horizontal direction (e.g., an “in-plane” direction, along the x-direction as shown, within an xy-plane, in a direction within or parallel to a surface of the substrate 520). In some other implementations of transistor architecture 500, the channel portion may support a conductive path in a vertical direction (e.g., an “out-of-plane” direction, along the z-direction, in a direction perpendicular to or otherwise away from a surface of the substrate 520). Although the example of FIG. 5 illustrates an implementation of the transistor architecture 500 for a channel having two channel portions 540, the transistor architecture 500 may be implemented with any quantity of one or more channel portions 540 for a given transistor.

A gate portion 550 may be physically separated from the channel portions 540 by gate insulation portions 560, with the gate insulation portion 560-a illustrated with hidden lines that show how gate insulation portions 560 may extend through the gate portion 550 and around the channel portions 540. The gate portion 550 may be formed from an electrically conductive material such as a metal or metal alloy (e.g., a metal gate electrode), or a polycrystalline semiconductor (e.g., polysilicon), among other conductor or semiconductor arrangements formed beside or along the channel portion. The transistor architecture 500 illustrates an example of gate portion 550 being located along or around all sides (e.g., four sides) of each channel portion 540 (e.g., around sides 580-a, 580-b, 580-c, and 580-d of the channel portion 540-a). Thus, the channel portions 540 of the transistor architecture 500 illustrate an example of channel portions that are located through the gate portion 550 (e.g., with the gate portion 550 wrapping around each channel portion 540, as an all-around gate). The channel portions 540-a may be referred to as channel filaments or ribbons, and may have various cross-sectional shapes (e.g., a circular, oval, or irregular cross-section), including but not limited to the rectangular shape shown.

In some examples, the transistor architecture 500 may be operable as an n-type transistor, where applying a relatively positive voltage to the gate portion 550 that is above a threshold voltage activates the channel portions 540 or otherwise enables a conductive path between the terminals 570-a-1 and 570-a-2. In some such examples, the channel portions 540 may include portions having n-type doping or n-type semiconductor, which may include an undoped portion between them, or may include a portion having p-type doping or p-type semiconductor between them. In some other examples, the transistor architecture 500 may be operable as a p-type transistor, where applying a relatively negative voltage to the gate portion 550 that is above a threshold voltage activates the channel portions 540 or otherwise enables a conductive path between the terminals 570-a-1 and 570-a-2. In some such examples, the channel portions 540 may include portions having p-type doping or p-type semiconductor, which may include an undoped portion between them, or may include a portion having n-type doping or n-type semiconductor between them.

In some examples, circuitry operable to support access operations on memory cells in memory array 170 may be formed to include at least some transistors formed in accordance with the transistor architecture 500. In some examples, circuitry in dies 205 (e.g., in one or more interface blocks 220, in a host processor 210, where applicable), in dies 240 (e.g., in one or more interface blocks 260, as cell selection transistors in one or more memory arrays 250), or both may be formed to include respective sets of transistors each having the arrangement of the transistor architecture 500. Although the transistor architecture 500 may be more complex to manufacture than the transistor architectures 300 or 400 (e.g., related to deposition or epitaxy of semiconductor for channel portions 540, or operations associated with forming an all-around gate such as the gate portion 550), in some examples, the transistor architecture 500 may have other favorable performance such as improved channel characteristics (e.g., lower leakage, lower threshold voltages, steeper activation performance, lower activation latency) relative to the transistor architectures 300 and 400, among other characteristics that may be favorable for certain aspects of a data path.

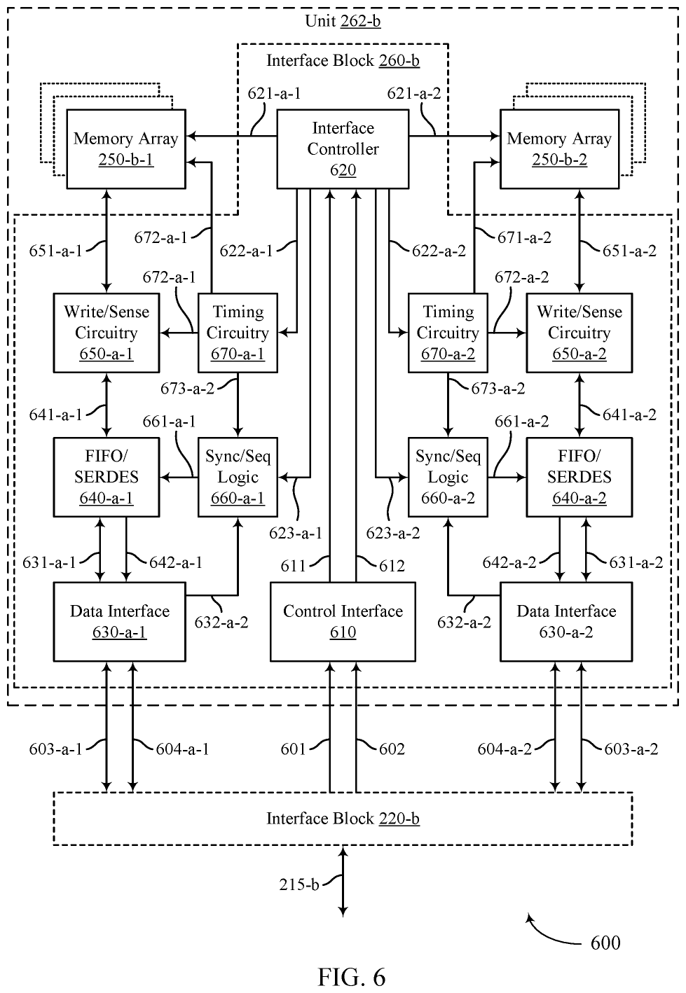

FIG. 6 illustrates an example of an architecture 600 that supports transistor architectures in coupled semiconductor systems in accordance with examples as disclosed herein. The architecture 600 illustrates an example of an interface block 260-b (e.g., of a die 240) and an interface block 220-b (e.g., of a die 205) that may be coupled between memory arrays 250-b and a bus 215-b (e.g., a host interface). In the example of architecture 600, the interface block 260-b may be communicatively coupled with the interface block 220-b via one or more channels, such as channels associated with a bus 601, a bus 602, a bus 603, and a bus 604, each of which may be examples of one or more signal paths of a bus 225 and a bus 265, as well as a bus 290, where applicable. Circuitry of the interface block 260-b may be included in an example of a unit 262-b along with its corresponding memory arrays 250-b. Although the example of FIG. 6 depicts a certain distribution of components between the interface block 220-b and the interface block 260-b (e.g., between a die 205 and a die 240), such components may be distributed differently among interface blocks or dies in accordance with the described techniques. Different portions of the architecture 600 may implement different transistor architectures, such as transistor architectures 300, 400, and 500.

The interface block 260-b includes a control interface 610 (e.g., a command interface), which may be configured to communicate signaling with the interface block 220-b. For example, the control interface 610 may include circuitry (e.g., a receiver, one or more latches) configured to receive control signaling (e.g., modulated control signaling, access command signaling, configuration signaling, address signaling, such as row address signaling or column address signaling) over the bus 601 (e.g., associated with a control channel). The control interface 610 also may include circuitry configured to receive clock signaling (e.g., clock signaling associated with the control interface 610, clock signaling having one or more phases, such as true and complement phases, dk_t/c signaling from the interface block 220-b) over the bus 602 (e.g., associated with a clock channel, such as a control clock channel), which the control interface 610 may use for receiving the control signaling of the bus 601 (e.g., for triggering the one or more latches). The control interface 610 may transmit (e.g., forward) the control signaling over a bus 611, and may transmit the clock signaling over a bus 612 (e.g., for timing of other operations of the interface block 260-b), each of which may be received by an interface controller 620.

The interface block 260-b also includes two data interfaces 630 (e.g., data interfaces 630-a-1 and 630-a-2), which also may be configured to communicate signaling with the interface block 220-b. Each data interface 630 may include corresponding buses and circuitry, the operation of which may be associated with (e.g., controlled by, coordinated with, operated based on) control signaling via the control interface 610. Although the example of interface block 260-b includes two such data interfaces 630 associated with the control interface 610 (e.g., in a “channel pair” arrangement), the described techniques for an interface block 260 may include any quantity of one or more data interfaces 630, and associated buses and circuitry, for a given control interface 610 of the interface block 260. Each data interface 630 may be associated with respective data path circuitry, which may include respective first-in-first-out (FIFO) and serialization/deserialization (SERDES) circuitry (e.g., FIFO/SERDES), respective write/sense circuitry 650, respective synchronization and sequencing circuitry (e.g., sync/seq logic 660), and respective timing circuitry 670, along with interconnecting signal paths (e.g., one or more buses). However, in some other examples, data path circuitry may be arranged in a different manner, or may include different circuitry components, which may include circuitry that is dedicated to respective data paths, or shared among data paths, or various combinations thereof. Each data interface 630 also may be associated with a respective set of one or more memory arrays 250. In some examples, each memory array 250 may be understood to include respective addressing circuitry such as bank logic or decoders (e.g., a row decoder, a column decoder), among other array circuitry (e.g., sense amplifiers, latches). However, in some other examples, at least a portion of such circuitry may be included in the interface block 260.

Each data interface 630 may include circuitry (e.g., one or more latches, one or more drivers) configured to communicate (e.g., receive, transmit) data signaling (e.g., modulated data signaling, DQ signaling) over a respective bus 603 (e.g., associated with a data channel). Each data interface 630 also may include circuitry to communicate clock signaling over a respective bus 604 (e.g., associated with a clock channel, such as a data clock channel), which may support clock signal reception by the data interface 630 (e.g., first clock signaling associated with the data interface 630, clock signaling having one or more phases, such as true and complement phases, DQS_t/c signaling from the interface block 220-b, clock signaling associated with data reception or write operations), or clock signal transmission by the data interface 630 (e.g., second clock signaling associated with the data interface 630, RDQS_t/c signaling to the interface block 220-b, clock signaling associated with data transmission or read operations), or both. Each data interface 630 may transmit clock signaling (e.g., received clock signaling, DQS_t/c signaling) over a respective bus 632 (e.g., for timing of other operations of the interface block 260-b).

The interface controller 620 may support various control or configuration functionality of the interface block 260-b for accessing or otherwise managing operations of the coupled memory arrays 250-b. For example, the interface controller 620 may support access command coordination or configuration, latency or timing compensation, access command buffering (e.g., in accordance with a first-in-first-out FIFO or other organizational scheme), mode registers or logic for configuration settings, or test functionality, among other functions or combinations thereof. For each data path of the interface block 260 (e.g., a data path associated with a respective data interface 630, or an aggregate data path that includes all of the data interfaces 630 of an interface block 260), the interface controller 620 may be configured to transmit signaling to the respective memory arrays 250 over a bus 621 (e.g., address signaling, such as a row address or row activation signaling), to transmit signaling to the respective timing circuitry 670 over a bus 622 (e.g., timing signaling, which may be based on clock signaling received via the bus 612, configuration signaling), and to transmit signaling to the respective sync/seq logic 660 over a bus 623 (e.g., timing signaling, which may be based on clock signaling received via the bus 612, configuration signaling).

For each data path, the respective timing circuitry 670 may support timing of various operations (e.g., activations, coupling operations, signal latching, signal driving) relative to timing signaling received over a bus 622. For example, timing circuitry 670 may include a timing chain (e.g., a global column timing chain) configured to generate one or more clock signals or other initiation signals for controlling operations of the respective data path, and such signaling may include transitions (e.g., rising edge transitions, falling edge transitions, on/off transitions) that are offset from, at a different rate than, or otherwise different from transitions of signaling over the bus 622 to support a given operation or combination of operations. For example, timing circuitry 670 may be configured to transmit signaling to the respective memory arrays 250 over a bus 671 (e.g., column selection signaling, column address signaling), to transmit signaling to the respective write/sense circuitry 650 over a bus 672 (e.g., latch or driver timing signaling), and to transmit signaling to the respective sync/seq logic over a bus 673 (e.g., timing signaling).

For each data path, the respective FIFO/SERDES 640 may be configured to convert between data signaling of a first bus width (e.g., a relatively wide bus width, associated with a bus 641 (e.g., a data read/write (DRW) bus), having a relatively larger quantity of signal paths) and a second bus width (e.g., a relatively narrow bus width, associated with a bus 631, having a relatively smaller quantity of signal paths). In some examples, such a conversion may be accompanied by changing a rate of signaling between the bus 641 and the bus 631 (e.g., to maintain a given throughput). For example, a FIFO/SERDES 640 may support a conversion between the bus 641 having a bus width of 288 signal paths (e.g., for signaling Dat[287:0]) and the bus 631 having a bus width of 72 signal paths (e.g., for signaling DQ[71:0]), in which case a rate of signaling over the bus 631 may be four times as fast as a rate of signaling over the bus 641. In various examples, the FIFO/SERDES may receive data signaling over the bus 631 and transmit data signaling over the bus 641 (e.g., to support a write operation), or may receive data signaling over the bus 641 and transmit data signaling over the bus 631 (e.g., to support a read operation). In some examples (e.g., to support a read operation), the FIFO/SERDES 640 may be configured to transmit clock signaling (e.g., RDQS_t/c signaling) to the data interface 630, which may be forwarded to the interface block 220-b (e.g., over a bus 604, for reception of data signaling by the interface block 220-b received over a bus 631).

The timing or other synchronization of operations performed by the FIFO/SERDES 640 may be supported by one or more clock signals, among other signaling, received from the respective sync/seq logic 660 (e.g., over a bus 661). For example, the sync/seq logic 660 may generate or otherwise coordinate clock signaling to support the different rates of signaling of the bus 631 and the bus 641 (e.g., based on clock signaling received over a bus 632 and a bus 673). Additionally, or alternatively, the FIFO/SERDES 640 may operate in a direction (e.g., for data transmission to a data interface 630, for data reception from a data interface 630) or other mode based on configuration signaling received from the sync/seq logic 660.

For each data path, the respective write/sense circuitry 650 may be configured to support the accessing (e.g., data signaling, write signaling, read signaling) of the respective set of one or more memory arrays 250. For example, the write/sense circuitry 650 may be coupled with the memory arrays 250 over a bus 651 (e.g., a global input/output (GIO) bus), which may include respective signal paths associated with each memory array 250, or may include signal paths that are shared for all of the memory arrays 250 of the set, in which case the memory array circuitry may include multiplexing circuitry operable to couple the bus 651 with a selected one of the memory arrays 250. In some examples, a bus 651 may include a same quantity of signal paths as a bus 641 (e.g., for signaling GIO[287:0]). In some examples, a bus 651 may include a same quantity of signal paths as a quantity of columns in each memory array 250. In some other examples, the memory arrays 250 may include a quantity of columns that is an integer multiple of the quantity of signal paths of a bus 651, in which case the memory array circuitry (e.g., each memory array 250) may include decoding circuitry operable to couple a subset of columns of memory cells, or associated circuitry, with the bus 651.

To support write operations, the write/sense circuitry 650 may be configured to drive signaling (e.g., over the bus 651) that is operable to write one or more logic states to memory cells of the memory arrays 250 (e.g., based on data received over a bus 641, based on timing signaling received over a bus 671, based on data signaling received over a bus 603 and on control signaling received over a bus 601). In some examples, such signaling may be transmitted to supporting circuitry of or otherwise associated with the memory arrays 250 (e.g., as an output of signals corresponding to logic states to be written), such as sense amplifier circuitry, voltage sources, current sources, or other driver circuitry operable to apply a bias across a storage element of the memory cells (e.g., across a capacitor, across a ferroelectric capacitor), or apply a charge, a current, or other signaling to a storage element of the memory cells (e.g., to apply a current to a chalcogenide or other configurable memory material, to apply a charge to a gate of a NAND memory cell), among other examples.

To support read operations, the write/sense circuitry 650 may be configured to receive signaling (e.g., over the bus 651) that the write/sense circuitry 650 may further amplify for communication through the interface block 260-b. For example, the write/sense circuitry 650 may be configured to receive signaling corresponding to logic states read from the memory arrays 250, but at a relatively low driver strength (e.g., relatively ‘analog’ signaling, which may be associated with a relatively low drive strength of sense amplifiers of the memory arrays 250, such as p-type n-type sense amplifiers (PNSA)). The write/sense circuitry 650 may thus include further sense amplification (e.g., a data sense amplifier (DSA) or other latch between each signal path of the bus 651 and a respective signal path of the bus 641), which each may have a relatively high drive strength (e.g., for driving relatively ‘digital’ signaling over the bus 641).

The features of the architecture 600 may be duplicated in various quantities and arrangements to support a semiconductor system having multiple dies, such as various examples of a system 200. In an example implementation, each die 240 may be configured with 64 instances of the interface block 260-b (e.g., 64 units 262-b, each associated with one or more data paths), which may support a data signaling width of 9,216 signal paths for each die 240 (e.g., where each bus 603 of a channel pair is associated with 72 signal paths). For a system 200 having a stack of eight dies 240 coupled with a die 205, the die 205 may thus be configured with 512 instances of the interface block 220-b, thereby supporting an overall data signaling width of 73,738 signal paths for the system 200. However, in other implementations, dies 205 and dies 240 may be configured with different quantities of interface blocks 220 and 260, respectively, and a system 200 may be configured with different quantities of dies 240 per die 205. By dividing memory access circuitry among multiple semiconductor dies (e.g., a die 205 and one or more dies 240) in accordance with one or more of the described techniques, a system 200 may thus be configured with an increased throughput of information, or a greater storage density, among other advantages, compared with other techniques for configuring a memory system.

Dividing memory access circuitry, such as data path circuitry between memory cells and a host interface, among multiple semiconductor dies may allow different transistor fabrication techniques to be used for different portions of the memory access circuitry. For example, a first set of one or more dies or wafers (e.g., associated with dies 240) may be fabricated using a first process flow (e.g., a memory manufacturing flow), which may be associated with fabricating transistors of a first portion of the memory device circuitry (e.g., host interface logic in the memory stack). In some implementations, transistors of the first set of dies may be associated with relatively low leakage, or relatively low manufacturing cost (e.g., due to the standardized or commoditization of memory chips) compared to transistors of the second die. Transistors of the first die may also include layouts that integrate cell selection and multiplexing or decoding transistors with storage components.

A second set of one or more dies or wafers (e.g., associated with dies 205) may be fabricated using a second process flow (e.g., logic manufacturing flow), which may be associated with fabricating transistors of a second portion of the memory access circuitry. In some implementations, transistors of the second die may be associated with relatively high versatility, implementation in a set of standards, relatively high performance, relatively high current gain, relatively high switching speed, relatively low switching power, relatively smaller geometry, a relatively high quantity of interconnect layers, relatively high interconnect density, relatively high circuit density, relatively high power density, or a combination thereof compared to the transistors of the first die. Transistors of a second die may allow for customized design with relatively lower barriers to modification or customization of host facing protocols or interfaces, which may enable multiple product stock keeping units with an identical memory manufacturing flow. The second process flow may also allow for long-term backside communications protocol to inexpensive memory, reducing memory cost in a system over multiple design iterations. This may allow changes to the host communications protocol without changing the memory communications protocol. Portions of the circuitry (e.g., DRAM, Logic CMOS) may benefit from being processed separately from other portions of the circuitry (e.g., memory elements) since various portions of the circuitry may have different processing considerations (e.g., integration requirements, thermal considerations) in order to improve their respective characteristics such as performance and uniformity.

In a DRAM implementation, for example, memory cells of memory arrays 250 may each be associated with a storage component (e.g., a capacitor) and a cell selection component (e.g., a cell selection transistor). Such cell selection transistors may be implemented in accordance with the transistor architecture 300 or the transistor architecture 400, which may be different from transistors of a data path between the memory cells and a host interface. A technique for forming cell selection transistors may be selected based on relatively low cost or complexity, and compatibility with forming storage components, such as capacitors (e.g., process compatibility, area density compatibility), to support a commoditization of memory chips.

Additionally, or alternatively, multiplexing, decoding, or sense amplification transistors (e.g., associated with memory arrays 250), or any combination thereof may be implemented in accordance with the transistor architecture 300 or the transistor architecture 400, which may, in some examples, be a same transistor architecture as cell selection transistors. In some such examples, such a transistor architecture may be the same as a transistor architecture implemented for a portion of a data path, such as one or more of the components of the interface block 260-b described with architecture 600 (e.g., where transistors of the interface block 260-b may be implemented in accordance with the transistor architecture 300 or the transistor architecture 400). In some other examples, an architecture for cell selection, decoding, multiplexing, or sense amplification transistors may be different from the transistor architecture implemented for one or more of the components of the interface block 260-b, which may include implementations on a same die or a different die (e.g., where memory arrays 250 and interface blocks 260 may be implemented on separate dies). For example, in some implementations, memory arrays 250 (e.g., including cell selection transistors, decoding transistors, multiplexing transistors, sense amplification transistors, or any combination thereof) may be implemented on a first die using a first transistor configuration (e.g., in accordance with transistor architecture 300 or 400), and components of the interface block 260-b may be implemented on a second die using a second transistor configuration (e.g., in accordance with the transistor architecture 400 or 500).

Additionally, or alternatively, transistors of an interface block 220, or a host processor 210 (e.g., when included in a same die 205 as an interface block 220), or any combination thereof, may be implemented in accordance with the transistor architecture 400 or the transistor architecture 500, among other transistor architectures than may be different from a transistor architecture implemented in dies 240, for example. Such techniques may be implemented for higher-performance logic or processing transistors, which may not be necessary in commoditized memory dies (e.g., due to relatively higher cost, higher complexity, or unnecessarily dense layouts of such transistors that may be less suitable for integration with memory cells or other parts of a data path.

Thus, in accordance with these and other examples, different portions of a system, such as a system 200 (e.g., including an architecture 600 or variation thereof, among other memory architectures), may implement different transistor architectures, such as transistor architectures 300, 400, and 500, on different dies of the system. For example, a transistor architecture associated with a first portion of a data path between memory cell storage components and a host interface may be different from a transistor architecture associated with a second portion of the data path. In some implementations, transistors of a first die may include cell selection transistors each having channels formed from a respective portion of a substrate of a first die (e.g., in accordance with transistor architecture 300 or 400), and transistors of a second die may include data path transistors each having channels that are either formed from a respective portion of a substrate of the second die (e.g., in accordance with transistor architecture 300 or 400), or from a portion of a semiconductor material formed above a substrate of the second die (e.g., in accordance with transistor architecture 500)

In some examples, a transistor architecture (e.g., transistor architecture 300) in a portion of the architecture 600 may have a gate portion that is located along a first quantity of sides (e.g., one side) of the respective channel, or a first quantity of channel portions (e.g., one channel portion), or both. Additionally, or alternatively, a transistor architecture (e.g., transistor architecture 400, transistor architecture 500) in a different portion of the architecture 600 may have a gate portion that is located along a second quantity of sides (e.g., three sides, four sides, all sides, as an all-around gate) of the respective channel, or a second quantity of channel portions (e.g., multiple channel portions, such as multiple channel portions 540), or both. In some examples, a transistor architecture (e.g., transistor architecture 500) in a portion of the architecture 600 may have channels located within the gate portion while the channels of a transistor architecture (e.g., transistor architecture 300) in a different portion of the architecture 600 may be located beside the gate portion. In some examples, the transistor architecture of a first portion of the architecture 600 may have channel portions that are aligned along a direction over a substrate (e.g., an in-plane direction, such as along an x-direction or along a y-direction), and a different transistor architecture of a second portion of the architecture 600 may have channel portions that are aligned along a direction away from a substrate (e.g., an out-of-plane direction, such as along a z-direction). In some examples, the two transistor architectures may have channel portions, gate portions, or gate dielectric portions associates with different cross-sectional areas, or different gate dielectric materials, or different gate dielectric thicknesses, or a combination thereof, among other differences that may be implemented differently between multiple dies. These and other techniques in accordance with examples as disclosed herein may be implemented to improve an alignment of fabrication, assembly, or performance characteristics with different functional parameters of different portions of semiconductor system circuitry, such as aspects of the architecture 600.

FIG. 7 shows a flowchart illustrating a method 700 that supports transistor architectures in coupled semiconductor systems in accordance with examples as disclosed herein. The operations of method 700 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 705, the method 700 may include providing a first semiconductor component (e.g., one or more dies, one or more wafers) including a plurality of memory storage elements and first circuitry configured to access the plurality of memory storage elements, the first circuitry including a plurality of first transistors each having a first channel portion formed from a respective portion of a first substrate of the first semiconductor component and each having a first gate portion operable to modulate a conductivity of the first channel portion, the first channel portions and the first gate portions associated with a first transistor architecture.

At 710, the method 700 may include providing a second semiconductor component (e.g., one or more dies, one or more wafers) including second circuitry configured to access the plurality of memory storage elements, the second circuitry including a plurality of second transistors each having a second channel portion and each having a second gate portion operable to modulate a conductivity of the second channel portion, the second channel portions and the second gate portions associated with a second transistor architecture that is different from the first transistor architecture.

At 715, the method 700 may include bonding the first semiconductor component with the second semiconductor component, the bonding including an electrical coupling between the first circuitry configured to access the plurality of memory storage elements and the second circuitry configured to access the plurality of memory storage elements.

In some examples, an apparatus (e.g., a manufacturing system) as described herein may perform a method or methods, such as the method 700. The apparatus may include features, circuitry, logic, means, or instructions (e.g., a non-transitory computer-readable medium storing instructions executable by a one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for providing a first semiconductor component including a plurality of memory storage elements and first circuitry configured to access the plurality of memory storage elements, the first circuitry including a plurality of first transistors each having a first channel portion formed from a respective portion of a first substrate of the first semiconductor component and each having a first gate portion operable to modulate a conductivity of the first channel portion, the first channel portions and the first gate portions associated with a first transistor architecture; providing a second semiconductor component including second circuitry configured to access the plurality of memory storage elements, the second circuitry including a plurality of second transistors each having a second channel portion and each having a second gate portion operable to modulate a conductivity of the second channel portion, the second channel portions and the second gate portions associated with a second transistor architecture that is different from the first transistor architecture; and bonding the first semiconductor component with the second semiconductor component, the bonding including an electrical coupling between the first circuitry configured to access the plurality of memory storage elements and the second circuitry configured to access the plurality of memory storage elements.

Aspect 2: The method or apparatus of aspect 1, where the plurality of first transistors are associated with a first portion of a data path between the plurality of memory storage elements and a physical host interface and the plurality of second transistors are associated with a second portion of the data path between the plurality of memory storage elements and the physical host interface.

Aspect 3: The method or apparatus of any of aspects 1 through 2, where the plurality of first transistors include cell selection transistors each having the first channel portion formed from the respective portion of the first substrate and the plurality of second transistors are associated with at least a portion of a data path between the cell selection transistors and a physical host interface.

Aspect 4: The method or apparatus of any of aspects 1 through 3, where bonding the first semiconductor component with the second semiconductor component includes operations, features, circuitry, logic, means, or instructions, or any combination thereof for fusing a plurality of first conductive contacts of the first semiconductor component with a plurality of second conductive contacts of the second semiconductor component to couple the first circuitry with the second circuitry.

Aspect 5: The method or apparatus of aspect 4, where bonding the first semiconductor component with the second semiconductor component includes operations, features, circuitry, logic, means, or instructions, or any combination thereof for fusing a first dielectric material at a surface of the first semiconductor component with a second dielectric material at a surface of the second semiconductor component.

Aspect 6: The method or apparatus of any of aspects 1 through 5, where the second channel portions of the plurality of second transistors are each formed from a respective portion of a second substrate of the second semiconductor component.

Aspect 7: The method or apparatus of any of aspects 1 through 6, where the first channel portions of the plurality of first transistors are associated with a contiguous first crystalline arrangement of the first substrate of the first semiconductor component and the second channel portions of the plurality of second transistors are associated with a contiguous second crystalline arrangement of the second substrate of the second semiconductor component.

Aspect 8: The method or apparatus of any of aspects 1 through 7, where the second channel portions of the plurality of second transistors are each formed from a respective semiconductor portion formed above a second substrate of the second semiconductor component.

Aspect 9: The method or apparatus of any of aspects 1 through 8, where the first transistor architecture is associated with each first gate portion being located along a first quantity of one or more sides of a respective first channel portion and the second transistor architecture is associated with each second gate portion being located along a second quantity of one or more sides of a respective second channel portion, the second quantity being different from the first quantity.

Aspect 10: The method or apparatus of aspects 1 through 9, where the first transistor architecture is associated with each first channel portion being located beside a respective first gate portion and the second transistor architecture is associated with each second channel portion being located within a respective second gate portion.

Aspect 11: The method or apparatus of any of aspects 1 through 10, where the plurality of first transistors include a plurality of planar transistors each having the first channel portion formed from the respective portion of the first substrate and the plurality of second transistors include a plurality of fin field effect transistors each having the second channel portion formed from a respective portion of a second substrate of the second semiconductor component.

Aspect 12: The method or apparatus of any of aspects 1 through 11, where the plurality of first transistors include a plurality of fin field effect transistors each having the first channel portion formed from the respective portion of the first substrate and the plurality of second transistors include a plurality of all-around gate field effect transistors each having the second channel portion formed above a second substrate of the second semiconductor component.

Aspect 13: The method or apparatus of any of aspects 1 through 12, where the plurality of first transistors each have a first quantity of first channel portions and the plurality of second transistors each have a second quantity of second channel portions that is different from the first quantity.

Aspect 14: The method or apparatus of any of aspects 1 through 13, where the first channel portions of the plurality of first transistors are aligned along a direction over the first substrate and the second channel portions of the plurality of second transistors are aligned along a direction away from a second substrate of the second semiconductor component.

Aspect 15: The method or apparatus of any of aspects 1 through 14, where the first channel portions of the plurality of first transistors are associated with a first cross-sectional area and the second channel portions of the plurality of second transistors are associated with a second cross-sectional area that is different from the first cross-sectional area.

Aspect 16: The method or apparatus of any of aspects 1 through 15, where the plurality of first transistors are associated with a first gate dielectric material of a first thickness between the first channel portions and the first gate portions and the plurality of second transistors are associated with a second gate dielectric material of a second thickness between the second channel portions and the second gate portions, the second thickness being different from the first thickness.

FIG. 8 shows a flowchart illustrating a method 800 that supports transistor architectures in coupled semiconductor systems in accordance with examples as disclosed herein. The operations of method 800 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 805, the method 800 may include providing a first semiconductor component (e.g., one or more dies, one or more wafers) including a plurality of memory cells and a first portion of a data path between the plurality of memory cells and a physical host interface, the first portion of the data path including a plurality of first transistors associated with a first transistor architecture.

At 810, the method 800 may include providing a second semiconductor component (e.g., one or more dies, one or more wafers) including a second portion of the data path between the plurality of memory cells and the physical host interface, the second portion of the data path including a plurality of second transistors associated with a second transistor architecture that is different from the first transistor architecture.

At 815, the method 800 may include bonding the second semiconductor component with the first semiconductor component, the bonding including an electrical coupling of the second portion of the data path with the first portion of the data path based at least in part on fusing a plurality of second conductive contacts of the second semiconductor component with a plurality of first conductive contacts of the first semiconductor component.

In some examples, an apparatus (e.g., a manufacturing system) as described herein may perform a method or methods, such as the method 800. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 17: A method or apparatus including operations, features, circuitry, logic, means, or instructions, or any combination thereof for providing a first semiconductor component including a plurality of memory cells and a first portion of a data path between the plurality of memory cells and a physical host interface, the first portion of the data path including a plurality of first transistors associated with a first transistor architecture; providing a second semiconductor component including a second portion of the data path between the plurality of memory cells and the physical host interface, the second portion of the data path including a plurality of second transistors associated with a second transistor architecture that is different from the first transistor architecture; and bonding the second semiconductor component with the first semiconductor component, the bonding including an electrical coupling of the second portion of the data path with the first portion of the data path based at least in part on fusing a plurality of second conductive contacts of the second semiconductor component with a plurality of first conductive contacts of the first semiconductor component.

It should be noted that the methods described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 18: An apparatus, including: a first semiconductor component (e.g., one or more dies, one or more wafers) including a plurality of memory storage elements and first circuitry configured to access the plurality of memory storage elements, the first circuitry including a plurality of first transistors each having a first channel portion formed from a respective portion of a first substrate of the first semiconductor component and each having a first gate portion operable to modulate a conductivity of the first channel portion, the first channel portions and the first gate portions associated with a first transistor architecture; and a second semiconductor component (e.g., one or more dies, one or more wafers) coupled with the first semiconductor component and including second circuitry configured to access the plurality of memory storage elements, the second circuitry including a plurality of second transistors each having a second channel portion and each having a second gate portion operable to modulate a conductivity of the second channel portion, the second channel portions and the second gate portions associated with a second transistor architecture that is different from the first transistor architecture.

Aspect 19: The apparatus of aspect 18, where the plurality of first transistors are associated with a first portion of a data path between the plurality of memory storage elements and a physical host interface; and the plurality of second transistors are associated with a second portion of the data path between the plurality of memory storage elements and the physical host interface.

Aspect 20: The apparatus of any of aspects 18 through 19, where the plurality of first transistors include cell selection transistors each having the first channel portion formed from the respective portion of the first substrate; and the plurality of second transistors are associated with at least a portion of a data path between the cell selection transistors and a physical host interface.

Aspect 21: The apparatus of any of aspects 18 through 20, where the coupling of the second semiconductor component with the first semiconductor component includes a coupling of the second circuitry configured to access the plurality of memory storage elements with the first circuitry configured to access the plurality of memory storage elements via a fusion between a plurality of second conductive contacts of the second semiconductor component with a plurality of first conductive contacts of the first semiconductor component.

Aspect 22: The apparatus of aspect 21, where the coupling of the second semiconductor component with the first semiconductor component further includes a fusion of a second dielectric material at a surface of the second semiconductor component with a first dielectric material at a surface of the first semiconductor component.

Aspect 23: The apparatus of any of aspects 18 through 22, where the second channel portions of the plurality of second transistors are each formed from a respective portion of a second substrate of the second semiconductor component.

Aspect 24: The apparatus of aspect 23, where the first channel portions of the plurality of first transistors are associated with a contiguous first crystalline arrangement of the first substrate of the first semiconductor component; and the second channel portions of the plurality of second transistors are associated with a contiguous second crystalline arrangement of the second substrate of the second semiconductor component.

Aspect 25: The apparatus of any of aspects 18 through 24, where the second channel portions of the plurality of second transistors are each formed from a respective semiconductor portion formed above a second substrate of the second semiconductor component.

Aspect 26: The apparatus of any of aspects 18 through 25, where the first transistor architecture is associated with each first gate portion being located along a first quantity of one or more sides of a respective first channel portion; and the second transistor architecture is associated with each second gate portion being located along a second quantity of one or more sides of a respective second channel portion, the second quantity being different from the first quantity.

Aspect 27: The apparatus of any of aspects 18 through 26, where the first transistor architecture is associated with each first channel portion being located beside a respective first gate portion; and the second transistor architecture is associated with each second channel portion being located within a respective second gate portion.

Aspect 28: The apparatus of any of aspects 18 through 27, where the plurality of first transistors include a plurality of planar transistors each having the first channel portion formed from the respective portion of the first substrate; and the plurality of second transistors include a plurality of fin field effect transistors each having the second channel portion formed from a respective portion of a second substrate of the second semiconductor component.

Aspect 29: The apparatus of any of aspects 18 through 28, where the plurality of first transistors include a plurality of fin field effect transistors each having the first channel portion formed from the respective portion of the first substrate; and the plurality of second transistors include a plurality of all-around gate field effect transistors each having the second channel portion formed above a second substrate of the second semiconductor component.

Aspect 30: The apparatus of any of aspects 18 through 29, where the plurality of first transistors each have a first quantity of first channel portions; and the plurality of second transistors each have a second quantity of second channel portions that is different from the first quantity.

Aspect 31: The apparatus of any of aspects 18 through 30, where the first channel portions of the plurality of first transistors are aligned along a direction over the first substrate; and the second channel portions of the plurality of second transistors are aligned along a direction away from a second substrate of the second semiconductor component.

Aspect 32: The apparatus of any of aspects 18 through 31, where the first channel portions of the plurality of first transistors are associated with a first cross-sectional area; and the second channel portions of the plurality of second transistors are associated with a second cross-sectional area that is different from the first cross-sectional area.

Aspect 33: The apparatus of any of aspects 18 through 32, where the plurality of first transistors are associated with a first gate dielectric material of a first thickness between the first channel portions and the first gate portions; and the plurality of second transistors are associated with a second gate dielectric material of a second thickness between the second channel portions and the second gate portions, the second thickness being different from the first thickness.

An apparatus is described. The following provides an overview of aspects of the method or apparatus as described herein:

Aspect 34: An apparatus, comprising: a first semiconductor component including a plurality of memory cells and a first portion of a data path between the plurality of memory cells and a physical host interface, the first portion of the data path including a plurality of first transistors associated with a first transistor architecture; and a second semiconductor component coupled with the first semiconductor component and including a second portion of the data path between the plurality of memory cells and the physical host interface, the second portion of the data path including a plurality of second transistors associated with a second transistor architecture that is different from the first transistor architecture, where the coupling of the second semiconductor component with the first semiconductor component includes a coupling of the second portion of the data path with the first portion of the data path via a fusion of a plurality of second conductive contacts of the second semiconductor component with a plurality of first conductive contacts of the first semiconductor component.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. At any given time, a conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. An apparatus, comprising:
a first semiconductor component comprising a plurality of memory storage elements and first circuitry configured to access the plurality of memory storage elements, the first circuitry comprising a plurality of first transistors each having a first channel portion formed from a respective portion of a first substrate of the first semiconductor component and each having a first gate portion operable to modulate a conductivity of the first channel portion, the first channel portions and the first gate portions associated with a first transistor architecture; and
a second semiconductor component coupled with the first semiconductor component and comprising second circuitry configured to access the plurality of memory storage elements, the second circuitry comprising a plurality of second transistors each having a second channel portion and each having a second gate portion operable to modulate a conductivity of the second channel portion, the second channel portions and the second gate portions associated with a second transistor architecture that is different from the first transistor architecture.

2. The apparatus of claim 1, wherein:
the plurality of first transistors are associated with a first portion of a data path between the plurality of memory storage elements and a physical host interface; and
the plurality of second transistors are associated with a second portion of the data path between the plurality of memory storage elements and the physical host interface.

3. The apparatus of claim 1, wherein:
the plurality of first transistors comprise cell selection transistors each having the first channel portion formed from the respective portion of the first substrate; and
the plurality of second transistors are associated with at least a portion of a data path between the cell selection transistors and a physical host interface.

4. The apparatus of claim 1, wherein the coupling of the second semiconductor component with the first semiconductor component comprises a coupling of the second circuitry configured to access the plurality of memory storage elements with the first circuitry configured to access the plurality of memory storage elements via a fusion between a plurality of second conductive contacts of the second semiconductor component with a plurality of first conductive contacts of the first semiconductor component.

5. The apparatus of claim 4, wherein the coupling of the second semiconductor component with the first semiconductor component further comprises a fusion of a second dielectric material at a surface of the second semiconductor component with a first dielectric material at a surface of the first semiconductor component.

6. The apparatus of claim 1, wherein the second channel portions of the plurality of second transistors are each formed from a respective portion of a second substrate of the second semiconductor component.

7. The apparatus of claim 6, wherein:
the first channel portions of the plurality of first transistors are associated with a contiguous first crystalline arrangement of the first substrate of the first semiconductor component; and
the second channel portions of the plurality of second transistors are associated with a contiguous second crystalline arrangement of the second substrate of the second semiconductor component.

8. The apparatus of claim 1, wherein the second channel portions of the plurality of second transistors are each formed from a respective semiconductor portion formed above a second substrate of the second semiconductor component.

9. The apparatus of claim 1, wherein:
the first transistor architecture is associated with each first gate portion being located along a first quantity of one or more sides of a respective first channel portion; and
the second transistor architecture is associated with each second gate portion being located along a second quantity of one or more sides of a respective second channel portion, the second quantity being different from the first quantity.

10. The apparatus of claim 1, wherein:
the first transistor architecture is associated with each first channel portion being located beside a respective first gate portion; and
the second transistor architecture is associated with each second channel portion being located within a respective second gate portion.

11. The apparatus of claim 1, wherein:
the plurality of first transistors comprise a plurality of planar transistors each having the first channel portion formed from the respective portion of the first substrate; and
the plurality of second transistors comprise a plurality of fin field effect transistors each having the second channel portion formed from a respective portion of a second substrate of the second semiconductor component.

12. The apparatus of claim 1, wherein:
the plurality of first transistors comprise a plurality of fin field effect transistors each having the first channel portion formed from the respective portion of the first substrate; and
the plurality of second transistors comprise a plurality of all-around gate field effect transistors each having the second channel portion formed above a second substrate of the second semiconductor component.

13. The apparatus of claim 1, wherein:
the plurality of first transistors each have a first quantity of first channel portions; and
the plurality of second transistors each have a second quantity of second channel portions that is different from the first quantity.

14. The apparatus of claim 1, wherein:
the first channel portions of the plurality of first transistors are aligned along a direction over the first substrate; and
the second channel portions of the plurality of second transistors are aligned along a direction away from a second substrate of the second semiconductor component.

15. The apparatus of claim 1, wherein:
the first channel portions of the plurality of first transistors are associated with a first cross-sectional area; and
the second channel portions of the plurality of second transistors are associated with a second cross-sectional area that is different from the first cross-sectional area.

16. The apparatus of claim 1, wherein:
the plurality of first transistors are associated with a first gate dielectric material of a first thickness between the first channel portions and the first gate portions; and
the plurality of second transistors are associated with a second gate dielectric material of a second thickness between the second channel portions and the second gate portions, the second thickness being different from the first thickness.

17. A method, comprising:
providing a first semiconductor component comprising a plurality of memory storage elements and first circuitry configured to access the plurality of memory storage elements, the first circuitry comprising a plurality of first transistors each having a first channel portion formed from a respective portion of a first substrate of the first semiconductor component and each having a first gate portion operable to modulate a conductivity of the first channel portion, the first channel portions and the first gate portions associated with a first transistor architecture;
providing a second semiconductor component comprising second circuitry configured to access the plurality of memory storage elements, the second circuitry comprising a plurality of second transistors each having a second channel portion and each having a second gate portion operable to modulate a conductivity of the second channel portion, the second channel portions and the second gate portions associated with a second transistor architecture that is different from the first transistor architecture; and
bonding the first semiconductor component with the second semiconductor component, the bonding comprising an electrical coupling between the first circuitry configured to access the plurality of memory storage elements and the second circuitry configured to access the plurality of memory storage elements.

18. The method of claim 17, wherein:
the plurality of first transistors are associated with a first portion of a data path between the plurality of memory storage elements and a physical host interface; and
the plurality of second transistors are associated with a second portion of the data path between the plurality of memory storage elements and the physical host interface.

19. The method of claim 17, wherein bonding the first semiconductor component with the second semiconductor component comprises:
fusing a plurality of first conductive contacts of the first semiconductor component with a plurality of second conductive contacts of the second semiconductor component to couple the first circuitry with the second circuitry.

20. An apparatus, comprising:
a first semiconductor component comprising a plurality of memory cells and a first portion of a data path between the plurality of memory cells and a physical host interface, the first portion of the data path comprising a plurality of first transistors associated with a first transistor architecture; and
a second semiconductor component coupled with the first semiconductor component and comprising a second portion of the data path between the plurality of memory cells and the physical host interface, the second portion of the data path comprising a plurality of second transistors associated with a second transistor architecture that is different from the first transistor architecture,
wherein the coupling of the second semiconductor component with the first semiconductor component comprises a coupling of the second portion of the data path with the first portion of the data path via a fusion of a plurality of second conductive contacts of the second semiconductor component with a plurality of first conductive contacts of the first semiconductor component.
